(19) United States
(12) Patent Application Publication
(10) Pub. No.: US 2010/0164540 A1
(43) Pub. Date: Jul. 1, 2010

(54) Semiconductor Memory Device

(76) Inventor: Ki-Chang Kwean, Gyeonggi-do (KR)

Correspondence Address: IP & T Law Firm PLC, 7700 Little River Turnpike, Suite 207, Annandale, VA, 22003, US

(21) Appl. No.: 12/489,692

(22) Filed: Jun. 23, 2009

(30) Foreign Application Priority Data
Dec. 29, 2008 (KR) 10-2008-0135524

(51) Int. Cl. H03K 19/003

(52) U.S. Cl. 326/30

(57) ABSTRACT

A semiconductor memory device includes a reference voltage pad for receiving a reference voltage from an external device, a calibration resistor connected to a calibration node where an external resistor is connected to and having a resistor value decided according to a calibration code, and a calibration code generator for generating the calibration code by comparing a voltage of the calibration node and the reference voltage.

### CROSS-REFERENCE TO RELATED APPLICATIONS

The present invention claims priority of Korean patent application number 10-2008-0135524, filed on Dec. 29, 2008, which is incorporated by reference in its entirety.

### BACKGROUND OF THE INVENTION

The present invention relates to a semiconductor memory device, and more particularly, to an on-die termination device of a semiconductor memory device.

A transition time of a signal interfacing between semiconductor devices has been gradually shortened as an operation speed of an electric product increases. That is, the transition time has been shortened to minimize delay in transferring a signal between semiconductor devices. As the transition time of the signal is shortened, the influence of external noise increases and signal reflection caused by impedance mismatching at an interface end becomes significant.

The impedance mismatching is caused by external noise and the variation of a supply voltage, an operation temperature, and a manufacturing process. The impedance mismatching makes it difficult to transmit data at a high speed and distorts data outputted from a data output end of a semiconductor device.

In order to overcome the impedance mismatching problem, the high speed semiconductor device employs an on-die termination device. The on-die termination device is an impedance matching circuit disposed around a pad in an integrated chip. In a typical on-die termination scheme, a transmitting side performs a source termination operation using an output circuit and a receiving side performs a parallel termination operation using a termination circuit connected in parallel to a receiving circuit connected to the input pad.

Meanwhile, a ZQ calibration is a process of generating a pull-up calibration code and a pull-down calibration code that vary according to variation of process, voltage, and temperature (PVT) condition. Based on the generated pull-up and pull-down calibration codes, a resistance value of the on-die termination device (or a termination resistance value of a DQ pad in case of a semiconductor memory device) is controlled, thereby matching impedance.

FIG. 1 is a diagram illustrating an on-die termination device of a semiconductor memory device according to the prior art.

As shown in FIG. 1, the on-die termination device according to the prior art includes a first calibration resistor 101, a first calibration code generator 103, a second calibration resistor 109, a second calibration code generator 115, a reference voltage generator 121, and a termination resistor 127. A ZQ calibration operation is performed by the first calibration resistor 101, the first calibration code generator 103, the second calibration resistor 109, the second calibration code generator 114, and the reference voltage generator 121. A termination operation is performed by the termination resistor 127.

The first calibration resistor 101 and the first calibration code generator 103 generate a first calibration code PCODE<1:N>. The second calibration resistor 109 and the second calibration code generator 115 generate a second calibration code NCODE<1:N>. The first calibration code PCODE<1:N> corresponds to the pull-up calibration code and the second calibration code NCODE<1:N> corresponds to the pull-down calibration code.

The first calibration code generator 103 includes a comparator 105 and a pull-up counter 107. The comparator 105 generates a up/down signal UP_{—}1/DOWN_{—}1 by comparing a voltage of a calibration node ZQ connecting the ZQ pad 123 and the first calibration resistor 101 with a reference voltage VREF_ZQ generated from the reference voltage generator 121. The ZQ pad 123 is connected to an external resistance 125, for example, having 240Ω.

The reference voltage generator 121 generates a reference voltage VREF_ZQ of VDDQ/2 by dividing the supply voltage VDDQ with the resistances.

The pull-up counter 107 generates a first calibration code PCODE<1:N> in response to the up/down signal UP_{—}1/DOWN_{—}1. A plurality of resistances included in the first calibration resistor 101 are turned on or off in response to the first calibration code PCODE<1:N> and the resistance value of the first calibration resistor 101 is controlled according to the number of on/off resistances.

The first calibration resistor 101 pulls-up the calibration node ZQ and changes a voltage of the calibration node ZQ by the controlled resistance value of the first calibration resistor 101. The comparator 105 compares the changed voltage of the calibration node ZQ with the reference voltage VREF_ZQ again and outputs the up/down signal UP_{—}1/DOWN_{—}1. The resistance value of the first calibration resistor 101 becomes equal to the resistance value of the external resistance 125, and the voltage of the calibration node ZQ becomes identical to the reference voltage VREF_ZQ.

The first calibration code PCODE<1:N> is inputted to a dummy pull-up resistance 111 of the second calibration resistor 109. The dummy pull-up resistance 111 is formed identically to the first calibration resistor 101 to make a resistance value of the pull-down resistance 113 to be equal to that of the first calibration resistor 101. Therefore, resistance value of each resistor in the dummy pull-up resistance 111 is identical to a resistance value of each resistor in the first calibration resistor 101. Then, the generating the second calibration code NCODE<1:N> is similar to the generating the first calibration code PCODE<1:n>.

The second calibration code generator 115 includes a comparator 117 and a pull-down counter 119.

The comparator 117 outputs an up/down signal UP_{—}2/DOWN_{—}2 by comparing a reference voltage VREF_ZQ with a voltage of a node A and generates a second calibration code NCODE<1:N> in response to the up/down signal UP_{—}2/DOWN_{—}2. The pull-down resistance 113 of the second calibration resistor 109 pulls-down the node A. Finally, a voltage of the node A becomes equal to the reference voltage VREF_ZQ. That is, a resistance value of the pull-down resistor 113 becomes equal to a resistance value of the dummy pull-up resistance 111.

The termination resistor 127 includes a pull-up termination resistor 129 and a pull-down termination resistor 131. The termination resistor 127 performs a termination operation.

The first and second calibration codes PCODE<1:N> and NCODE<1:N> are inputted to the pull-up and pull-down termination resistors 129 and 131 respectively, and a termination resistance value for impedance matching is decided. That is, the pull-up termination operation for deciding a resistance value of the pull-up termination resistor 129 is performed based on the calibration code PCODE<1:N>, and the pull-down termination operation for deciding a resistance value of a pull-down termination resistor 131 is performed based on the pull-down calibration code NCODE<1:N>. Impedance matching with an external chip is achieved by the resistance value decided in the termination resistor 127.

FIG. 2 is a diagram describing operation of an on-die termination device shown in FIG. 1.

The semiconductor memory device 201 receives data transmitted through a transmission line and inputted to a DQ pad (not shown) through the input buffer 203. Here, the input buffer 203 determines a logical level of the data based on the reference voltage VREF_OUT from an external device. An output driver 205 outputs data stored in the semiconductor memory device 201 through the DQ pad and the transmission line.

The termination resistor 127 of the on-die termination device shown in FIG. 1 is connected to an output node of the output driver 205 and terminates a voltage of the transmission line, that is, a voltage of the output node of the output driver 205, as a predetermined voltage VTT. Therefore, the voltage VTT of the output node of the output driver 205 becomes VDDQ/2. This is because the calibration operation and the termination operation are performed based on the reference voltage VREF_ZQ of VDDQ/2 generated by the reference voltage generator 123.

In more detail, the input buffer 203 determines a logical level of data based on the reference voltage VREF_OUT as shown in FIG. 3. In FIG. 3, a solid line indicates the reference voltage VREF_OUT identical to the voltage VTT of the transmission line and a dotted line indicates the reference voltage VREF_OUT lower than the voltage of transmission line VTT.

The input buffer 203 may identify a high level and a low level of data with enough margin according to the reference voltage VREF_OUT indicated by the solid line. However, when the voltage VTT of the transmission line is higher than the reference voltage VREF_OUT, the voltage of data to be transmitted to the transmission line increases and such voltage increment makes the margin for identifying a low level of data to be insufficient. Therefore, the input buffer 203 may identify low level data as high level data. On the contrary, if the voltage VTT of the transmission line is lower than the reference voltage VREF_OUT, the input buffer 203 has difficulty to identify high level data.

For example, if the reference voltage VREF_OUT and the voltage VTT of the transmission line are about 1V and if data is swing from 0V to 2V, the input buffer 203 can identify a logical level of data with a margin of 1V. However, if the reference voltage VREF_OUT is 1V and the voltage VTT of the transmission line is about 1.5V, the data voltage is to swing from 0.5V to 2.5V. Therefore, a margin of the input buffer 203 for identifying a low level data is reduced.

If a transition time of data is long, the mismatching problem may not become serious. However, since the transition time of the signal has been shortened due to a high speed operation of a semiconductor device, the mismatching problem of the reference voltage VREF_OUT and the transmission line voltage VTT becomes significant. Meanwhile, such a problem of inaccurately identifying a logical level may effect not only to the data but also a control signal such as an address signal inputted to a semiconductor memory device.

### SUMMARY OF THE INVENTION

Embodiments of the present invention are directed to providing a semiconductor memory device having an improved characteristic of identifying an input signal.

In accordance with an aspect of the present invention, there is provided a semiconductor memory device including a reference voltage pad for receiving a reference voltage from an external device, a calibration resistor connected to a calibration node where an external resistor is connected to and having a resistor value decided according to a calibration code, and a calibration code generator for generating the calibration code by comparing a voltage of the calibration node and the reference voltage.

In accordance with another aspect of the present invention, there is provided a semiconductor memory device including a reference voltage pad for receiving a reference voltage from an external device, a first calibration resistor connected to a calibration node connected to an external resistor and having a resistor value decided according to a first calibration code, a first calibration code generator for generating the first calibration code by comparing a voltage of the calibration node and the reference voltage, a second calibration resistor connected to a predetermined node and having a resistor value decided according to the first calibration code and a second calibration code, a second calibration code generator for generating the second calibration code by comparing the reference voltage and a voltage of the predetermined node, and a termination resistor for matching impedance with a resistor value decided based on the first and second calibration codes.

### BRIEF DESCRIPTION OF THE DRAWINGS

FIG. 1 is a diagram illustrating an on-die termination device of a typical semiconductor memory device.

FIG. 2 is a diagram illustrating operation of an on-die termination device shown in FIG. 1.

FIG. 3 is a diagram illustrating that an input buffer determines a logical level of input data.

FIG. 4 is a diagram illustrating a semiconductor memory device in accordance with an embodiment of the present invention.

FIG. 5 is a diagram illustrating a semiconductor memory device in accordance with another embodiment of the present invention.

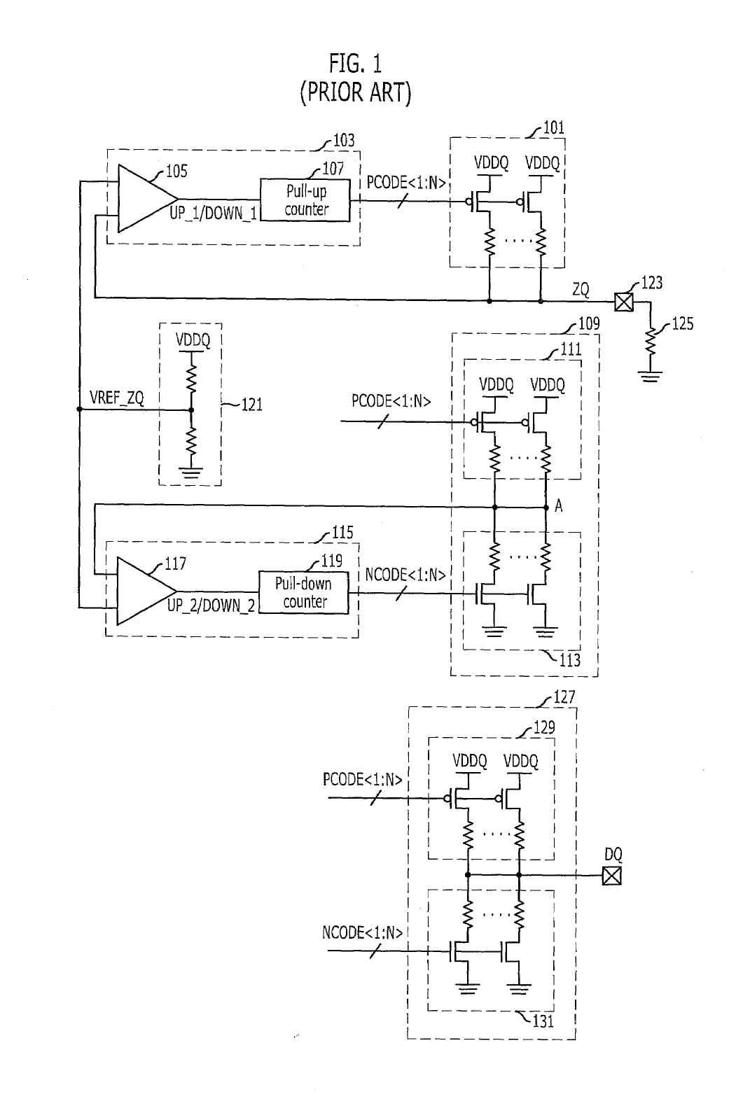

### DESCRIPTION OF SPECIFIC EMBODIMENTS

Other objects and advantages of the present invention can be understood by the following description, and become apparent with reference to the embodiments of the present invention.

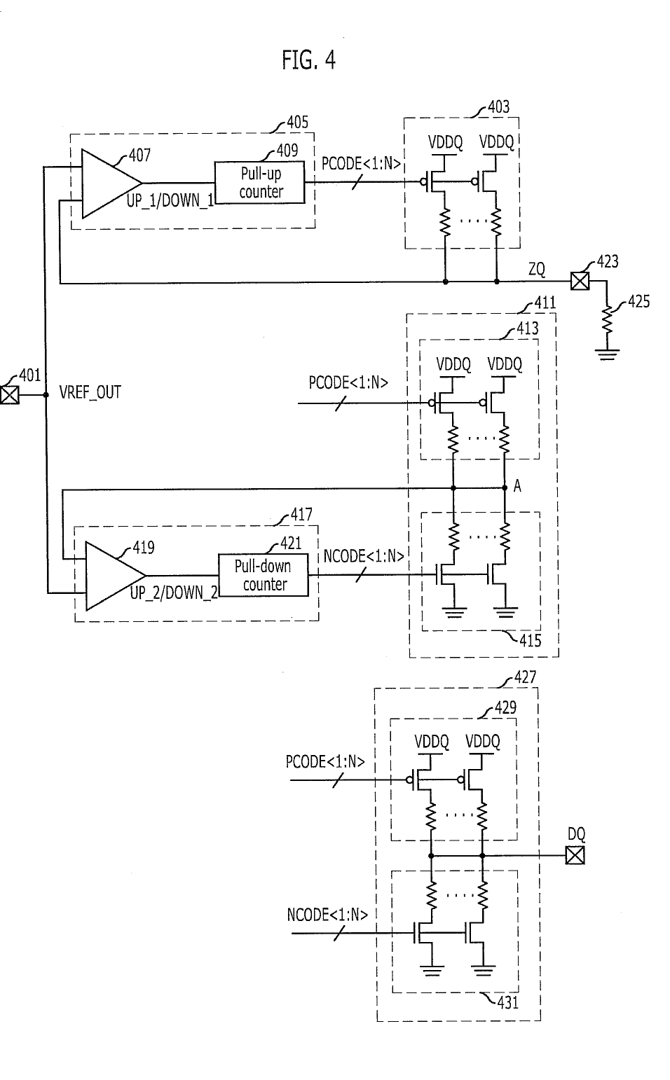

FIG. 4 is a diagram illustrating a semiconductor memory device in accordance with an embodiment of the present invention.

As shown in FIG. 4, the on-die termination device according to the present embodiment includes a reference voltage pad 401, a first calibration resistor 403, a first calibration code generator 405, a second calibration resistor 411, a second code generator 417, and a termination resistor 427.

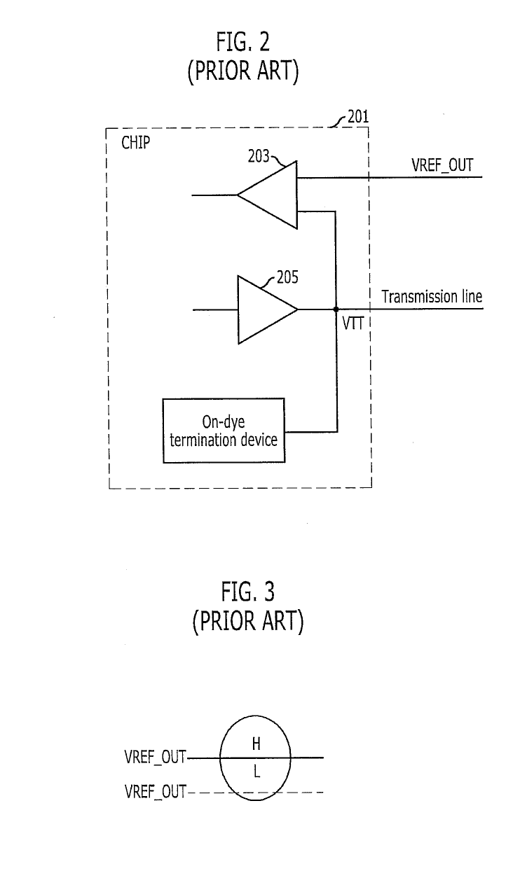

Unlike a conventional on-die terminal device, the on-die termination device according to the present embodiment uses a reference voltage VERF_OUT inputted from the reference voltage pad 401 to perform a calibration operation and a termination operation. As shown in FIG. 2, the reference voltage VREF_OUT inputted from the reference voltage pad 401 is a voltage used in the input buffer as a reference to determine a logical level of an input signal inputted to the input buffer.

Therefore, since the transmission line voltage VTT becomes identical to the reference voltage VREF_OUT as shown in FIG. 2, it is possible to minimize the reduction of a margin for determining a logical level of an input signal, where the margin is reduced by mismatching of the transmission line voltage VTT and the reference voltage VREF_OUT. Finally, identification performance can be improved according to the present invention. The reference voltage VREF_OUT inputted to the reference voltage pad 401 may be generated by a memory controller or a main board.

Hereinafter, a semiconductor memory device according to the present embodiment will be described in detail.

The first calibration code generator 405 includes a comparator 407 and a pull-up counter 409.

The comparator 407 generates an up/down signal UP_{—}1/DOWN_{—}1 by comparing a voltage of a calibration node ZQ connected with the first calibration resistor 403 with a reference voltage VREF_OUT inputted from the reference voltage pad 401.

The pull-up counter 409 generates a first calibration code PCODE<1:N> in response to the up/down signal UP_{—}1/DOWN_{—}1. A plurality of resistances included in the first calibration resistor 403 are turned on/off in response to the first calibration code PCODE<1:N> and control a resistance value of the first calibration resistor 403.

Each of the plurality of resistances performs a pull-up operation on the calibration node ZQ, and the voltage of the calibration node ZQ is changed by a resistance value of the first calibration resistor 403. The comparator 407 compares the changed voltage of the calibration node ZQ with the reference voltage VREF_OUT again and generates the up/down signal UP_{—}1/DOWN_{—}1. As a result, the resistance value of the first calibration resistor 403 becomes identical to the resistance value of an external resistor 45 connected to a ZQ pad, and a voltage of the calibration node ZQ becomes identical to the reference voltage VREF_OUT.

The first calibration code PCODE<1:N> is inputted to a dummy pull-up resistance 413 of the second calibration resistor 111. The dummy pull-up resistance 413 includes a plurality of resistances that are turned on or off in response to the first calibration code PCODE<1:N> like the first calibration resistor 403. Therefore, a resistance value of each resistance in the dummy pull-up resistance 413 becomes identical to the resistance value of each resistance in the first calibration resistor 403. Then, the generating the second calibration code NCODE<1:N> is similar to generating the first calibration code PCODE<1:N>.

The second calibration code generator 417 includes a comparator 419 and a pull-down counter 421.

The comparator 419 outputs an up/down signal UP_{—}2/DOWN_{—}2 by comparing a reference voltage with a voltage of a node A, and the pull-down counter 421 generates the second calibration code NCODE<1:N> in response to the up/down signal UP_{—}2/DOWN_{—}2. The pull-down resistor 415 of the second calibration resistor 411 includes a plurality of resistances that are turned on/off in response to the second calibration code NCODE<1:N>. The plurality of resistances perform a pull-down operation on the node A. Finally, the voltage of the node A becomes identical to the reference voltage VREF_OUT. That is, the resistance value of the pull-down resistor 415 becomes identical to the resistance value of the pull-up resistor 413.

The termination resistor 427 includes a pull-up termination resistor 429 and a pull-down terminal resistor 413 and performs a termination operation.

The first and second calibration codes PCODE<1:N> and NCODE<1:N> are inputted to the pull-up and pull-down termination resistors 429 and 431 and a termination resistance value is decided for impedance matching. The pull-up termination operation for deciding a resistance value of the pull-up termination resistor 429 is performed based on the first calibration code PCODE<1:N>. Also, the pull-down termination operation for deciding a resistance value of the pull-down termination resistor 431 is performed based on the second calibration code NCODE<1:N>.

Finally, the termination operation according to the present embodiment makes the transmission line voltage VTT to be identical to the reference voltage VREF_OUT. Therefore, the termination operation according to the present embodiment improves signal identification performance of the input buffer for determining a logical level of a signal based on the reference voltage VREF_OUT.

The termination resistor 427 may include one of a pull-up termination resistor 429 and a pull-down termination resistor 413 according to a location of the termination resistor 427. For example, the termination resistor 427 can pull-up or pull-down termination of a signal inputted to the input buffer if the termination resistor 427 is used as an input buffer in a predetermined semiconductor memory device. Accordingly, only one of the first and second calibration codes PCODE<1:N> and NCODE<1:N> can be generated. For example, if it is necessary to generate only the first calibration code PCODE<1:N>, the semiconductor memory device according to the present embodiment may include a reference voltage pad 401, a first calibration resistor 403, a first calibration code generator 405, and a pull-up termination resistor 429.

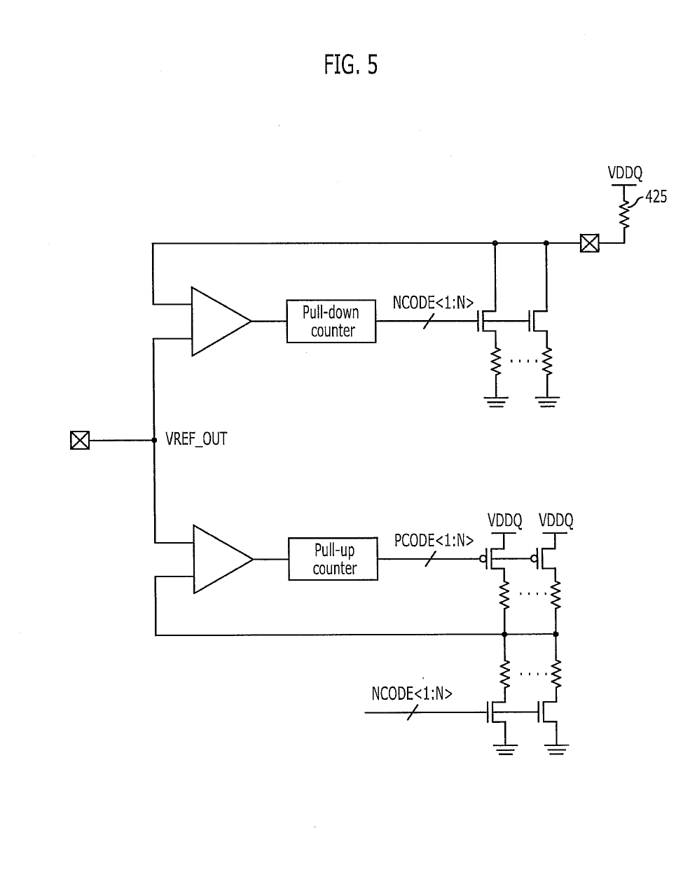

As shown in FIG. 5, in the semiconductor memory device according to another embodiment, an external resistor 425 is connected to a supply voltage VDDQ, not a ground voltage. Therefore, the second calibration code NCODE<1:N> is generated first and the first calibration code PCODE<1:N> may be generated later. Since the operation of generating the first and second calibration codes PCODE<1:N> and NCODE<1:N> were already described with reference to FIG. 4, the detail description thereof is omitted. Although it is not shown in FIG. 4, the termination resistor has the same structure of the termination resistor 427 shown in FIG. 4.

Embodiments of the present invention relate to an on-die termination device of a semiconductor memory device. The on-die termination device performs calibration operation using a reference voltage of an external device. Therefore, the on-die termination device according to the present embodiment performs the termination operation based on an external reference voltage and improves performance of identifying a signal inputted to a semiconductor memory device.

While the present invention has been described with respect to the specific embodiments, it will be apparent to those skilled in the art that various changes and modifications may be made without departing from the spirit and scope of the invention as defined in the following claims.

What is claimed is:

1. A semiconductor memory device, comprising:
a reference voltage pad for receiving a reference voltage from an external device;
a calibration resistor connected to a calibration node where an external resistor is connected to and having a resistor value decided according to a calibration code; and
a calibration code generator for generating the calibration code by comparing a voltage of the calibration node and the reference voltage.

2. The semiconductor memory device of claim 1, wherein the reference voltage is used in an input buffer that receives an input signal as a reference to determine a logical level of the input signal.

3. The semiconductor memory device of claim 1, wherein the calibration resistor is configured to be turned on/off in response to the calibration code and includes a plurality of resistances for pulling up or pulling down the calibration node.

4. The semiconductor memory device of claim 1, further comprising:
a termination resistor for matching impedance with a resistance value decided based on the calibration code.

5. A semiconductor memory device, comprising:
a reference voltage pad for receiving a reference voltage from an external device;
a first calibration resistor connected to a calibration node connected to an external resistor and having a resistor value decided according to a first calibration code;
a first calibration code generator for generating the first calibration code by comparing a voltage of the calibration node and the reference voltage;
a second calibration resistor connected to a predetermined node and having a resistor value decided according to the first calibration code and a second calibration code;
a second calibration code generator for generating the second calibration code by comparing the reference voltage and a voltage of the predetermined node; and
a termination resistor for matching impedance with a resistor value decided based on the first and second calibration codes.

6. The semiconductor memory device of claim 5, wherein the reference voltage is a reference voltage used in an input buffer as a reference for determining a logical level of the input signal.

7. The semiconductor memory device of claim 5, wherein the first calibration resistor is configured to be turned on/off in response to the first calibration code and includes a plurality of resistances for pulling up the calibration node.

8. The semiconductor memory device of claim 7, wherein the second calibration resistor includes:
a plurality of resistances turned on/off in response to the first calibration code and pulling up the predetermined node; and
a plurality of resistances turned on/off in response to the second calibration code and pulling down the predetermined node.

9. The semiconductor memory device of claim 5, wherein the termination resistor includes:
a pull-up termination resistor for performing a pull-up termination operation in response to the first calibration code; and
a pull-down termination resistor for performing a pull-down termination operation in response to the second calibration code.
